(19) United States
(12) Patent Application Publication
(10) Pub. No.: US 2025/0133894 A1
(43) Pub. Date: Apr. 24, 2025

(54) INDIUM ZINC TIN OXIDE TRANSPARENT ELECTRODE WITH PANI:PSS INTERMEDIATE LAYER

(71) Applicant: UNIVERSITY OF SEOUL INDUSTRY COOPERATION FOUNDATION, Seoul (KR)

(72) Inventors: Hyeok KIM, Seoul (KR); Swarup BISWAS, Seoul (KR); Yong Ju LEE, Sacheon-si (KR); Hyo Won JANG, Seoul (KR); Se Lim HAN, Gimpo-si (KR)

(21) Appl. No.: 18/920,270

(22) Filed: Oct. 18, 2024

(30) Foreign Application Priority Data
Oct. 18, 2023 (KR) 10-2023-0139193

(51) Int. Cl. H10K 30/82; C01G 19/00

(52) U.S. Cl. CPC H10K 30/82; C01G 19/006; C01P 2002/50; C01P 2004/03; C01P 2004/80; C01P 2006/40

(57) ABSTRACT

Provided is a transparent indium zinc tin oxide (IZTO) electrode with a PANI:PSS interlayer, wherein the PANI:PSS interlayer is formed on an upper surface of an IZTO film. Accordingly, it is possible to manufacture a transparent IZTO electrode with improved mechanical stability by forming a PANI:PSS interlayer to prevent fractures in the inorganic IZTO layer, thereby significantly improving the retention rate of the initial average visible transmittance (AVT) even after bending cycles and reducing sheet resistance.

### CROSS-REFERENCE TO RELATED APPLICATION

This application claims priority to and the benefit of Korean Patent Application No. 10-2023-0139193, filed on Oct. 18, 2024, the disclosure of which is incorporated herein by reference in its entirety.

### BACKGROUND

### 1. Field of the Invention

The present invention relates to a transparent indium zinc tin oxide electrode. More particularly, the present invention relates to a transparent indium zinc tin oxide electrode with improved mechanical stability by including a PANI:PSS interlayer.

### 2. Discussion of Related Art

As the market for various flexible electronic devices, such as flexible photovoltaic cells, flexible displays, electronic papers and so on, has grown remarkably in recent years, the demand for flexible transparent conductive oxide (TCO) films is rapidly increasing. TCO films are used as transparent electrodes in flexible devices, and the performance of flexible electronic devices directly depends on the physicochemical properties of the electrode, that is, the TCO film. Therefore, it is necessary to develop high-performance TCO films with very low sheet resistance, high transparency, high flexibility, and high mechanical stability (the bending effect on sheet resistance, transparency, etc. need to be minimized).

However, there are limitations on flexibility and durability due to the brittleness of the oxide material and the mismatch between the behavior of flexible polymer substrate and the TCO. Specifically, the transmittance reduction rate and the sheet resistance increase rate of TCO-based flexible electrodes significantly increase depending on the number of times they are bent and twisted. In the initial stage, indium tin oxide (ITO) films were widely used as TCOs for various flexible electronic devices due to their excellent electrical (sheet resistance ˜10 Ω·cm) and optical (average visible transmittance (AVT)˜85% in the visible range) properties. However, since ITO films have low mechanical stability, a low work function, and a high processing temperature, alternatives were sought to overcome these problems.

Later, to overcome the problems encountered when using ITO as a flexible electrode, attempts have been made to use various alternative TCO materials such as indium zinc oxide (IZO), zinc indium tin oxide (ZITO), indium tin zinc oxide (ITZO), and indium zinc tin oxide (IZTO). Among these TCO materials, the IZTO film has shown great potential as a transparent anode material in various flexible transparent electronic devices due to its high transparency, low sheet resistance, high work function (6.1 eV), and low processing temperature.

Recently, it was reported that in compression and relaxation tests using the IZTO film as a transparent electrode for a flexible organic solar cell, the IZTO film had an initial power conversion efficiency (PCE) value of up to 93.3% after being bent 1,000 times. Based on this result, the research team developed a highly flexible OPV by using IZTO deposited on a cyclic polymer substrate at a low temperature, and the device exhibited excellent mechanical properties (after 1,000 compression/relaxation tests with a compression strain of 33%, the PCE of the highly flexible OPV was maintained up to 94.8% of the initial value). As such, it can be seen that considerable efforts have been made in recent studies to optimize the processing conditions of the IZTO to achieve better performance. However, since research on the mechanical reliability of IZTO films is still limited, it is crucial to further improve the mechanical stability. To improve the mechanical reliability of IZTO films, various techniques have been attempted.

More recently, various organic polymer semiconductors such as poly(3,4-ethylenedioxythiophene): polystyrenesulfonate, polyaniline: polystyrenesulfonate (PANI:PSS), polyaniline: camphorsulfonic acid, and doped polypyrrole have been widely used as interlayers in a variety of organic electronic devices. PANI:PSS has recently exhibited great performance as a hole transporting material for OPVs. Due to its good processability, excellent mechanical stability, and high conductivity and environmental stability, the interaction between the transparent electrode and the active material is improved. In addition, it was found that due to its low acidity, PANI:PSS has a low etching effect on the TCO electrode of OPVs.

Based on the idea that PANI:PSS used as an interlayer of IZTO can help improve mechanical stability while maintaining transparency and sheet resistance, the present invention provides a transparent indium zinc tin oxide electrode with improved mechanical stability.

### SUMMARY OF THE INVENTION

The present invention is directed to providing a transparent indium zinc tin oxide (IZTO) electrode with improved mechanical stability.

In order to overcome the above problems, the present invention provides a transparent IZTO electrode including a PANI:PSS interlayer formed on an upper surface of an IZTO film.

The present invention also provides a transparent IZTO electrode, wherein the weight ratio of PANI to PSS of the PANI:PSS is 1:1.

The present invention also provides a transparent IZTO electrode, wherein an interlayer is formed by spin coating the PANI:PSS on the upper surface of the IZTO film at 3,000 rpm for 60 seconds.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a set of graphs showing the transmittance spectra of an IZTO film with a PANI:PSS interlayer according to an embodiment of the present invention and a conventional IZTO film before and after bending treatment, respectively;

FIG. 2 is a set of graphs showing AVT and normalized AVT values calculated at different numbers of bending cycles for an IZTO film with a PANI:PSS interlayer according to an embodiment of the present invention and a conventional IZTO film;

FIG. 3 is a graph showing sheet resistance values of a conventional IZTO film and an IZTO film with a PANI:PSS interlayer according to an embodiment of the present invention; and

FIG. 4 is a set of SEM images of a conventional IZTO film and an IZTO film with a PANI:PSS interlayer according to an embodiment of the present invention immediately before and after bending cycles.

### DETAILED DESCRIPTION OF EXEMPLARY EMBODIMENTS

The objects and effects of the present invention will become clear through the following detailed description, but are not limited to the following description. In addition, in the description of the present invention, when it is determined that the detailed description of known technologies related to the present invention may unnecessarily obscure the gist of the present invention, the detailed description will be omitted.

Hereinafter, embodiments of the present invention will be described in detail with reference to the attached drawings so that those skilled in the art can easily implement the present invention. However, the present invention may be implemented in various forms and thus is not limited to the embodiments disclosed below. In addition, in order to clearly disclose the present invention in the drawings, parts not related to the present invention are omitted, and identical or similar symbols in the drawings indicate identical or similar components.

In the present invention, there is provided an IZTO-based flexible transparent electrode with improved mechanical stability using an organic semiconductor PANI:PSS as an interlayer. Conventionally, PANI:PSS with a weight ratio of PANI to PSS of 1:1 was observed to have the highest conductivity. However, in the present invention, in order to improve mechanical stability to a more significant value, PANI:PSS with a fixed weight ratio of PANI to PSS of 1:1 was synthesized. In addition, a transparent electrode was manufactured by treating an IZTO film deposited on a flexible PI substrate with PANI:PSS.

Polyaniline (PANI) is an inexpensive common conjugated polymer and can be used as a hole transporting material (HTM) of OPVs for indoor applications due to its environmental stability, high transmittance, adjustable hole transport ability and low acidity. However, the processability, conductivity and water stability of PANI need to be improved. To overcome this problem, PSS-doped PANI (PANI:PSS), which is inexpensive, less acidic and water stable, is used.

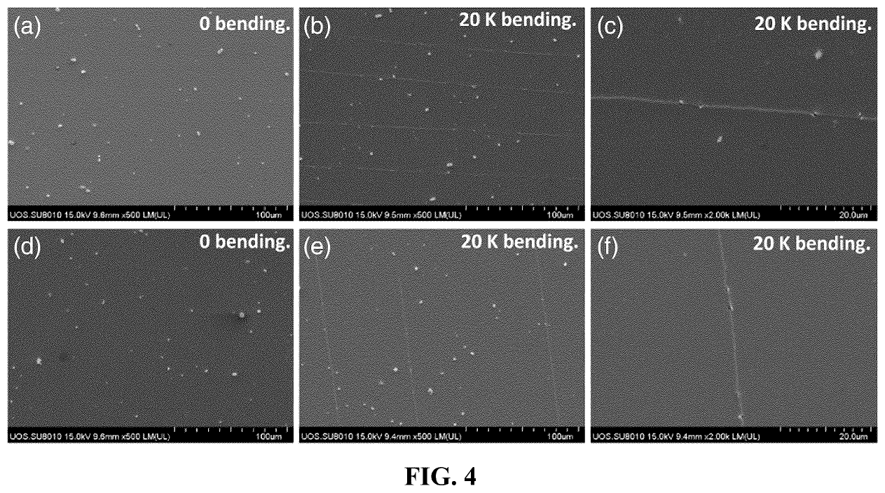

With reference to the contents described later, when comparing the transmittance spectra and sheet resistance values, which are recorded before and after bending a conventional pure IZTO film and a PANI:PSS-treated IZTO film 20,000 times, it can be seen that mechanical stress (i.e. bending) affects optical properties (transmittance) and electrical properties (sheet resistance) and the physical properties of the IZTO film are significantly reduced. This is because the PANI:PSS layer treatment may prevent the occurrence of cracks in the inorganic IZTO layer (see FIG. 4, scanning electron microscope (SEM) images).

Before examining the improved mechanical stability of the IZTO film with a PANI:PSS interlayer according to an embodiment of the present invention, a method of manufacturing the film according to an embodiment of the present invention will be described in detail with reference to the drawings.

### Materials

Aniline was purified through vacuum distillation before polymerization, and aniline (purity 99.5%, MW: 93.13) and 1,2-dichlorobenzene (DCB) (purity 98.0%, MW: 151.03) from Sigma-Aldrich were used. Ammonium peroxydisulfate (APS) (purity 98.0%, MW: 228.18), an oxidant from Samchun Chemical Co., Ltd., was used without any separate purification process. PSS (MW: 70,000) from Alfa Aesar was used, and deionized (DI) water (18 MΩ) was obtained using a RO 15 reverse osmosis system. In addition, a flexible PI film coated with IZTO (200 nm) was used.

### Method of Preparing PANI:PSS

An aniline solution was prepared by adding 2.15 mM (200 mg) aniline to 50 ml of deionized (DI) water, and the mixture was stirred at 1,000 rpm and 0 to 5° C. Afterward, 200 mg of PSS was added to the aniline solution and stirred at 1,000 rpm and 0 to 5° C. for 5 hours. At the same time, an APS (2.15 mM) solution added to 25 ml of deionized (DI) water was stirred at 1,000 rpm for 30 minutes, maintained at 0 to 5° C. for 5 hours, and then added dropwise to the aniline/PSS solution. Afterward, the mixture was maintained at 0 to 5° C. for 24 hours while stirring (at 1,000 rpm) to complete the reaction. As a result, PANI:PSS with water stability was obtained.

### Method of Forming PANI:PSS Interlayer

The processing step of forming a PANI:PSS interlayer on an IZTO film deposited on a PI substrate will be described. First, the substrate was mounted on hard glass using Scotch tape, and then the dust remaining on the IZTO surface was removed using a nitrogen (N₂) gas blower. Afterward, PANI:PSS was spin-coated on the IZTO film at 3,000 rpm for 60 seconds. The PI substrate was separated from the hard glass substrate and heated at 100° C. for 2 hours for further study.

### Method of Observing Properties

The transmittance spectrum (300-800 nm) of the IZTO film with a PANI:PSS interlayer, which was treated unlike the pure IZTO film, was recorded using Shimadzu UV-2401PC and TCC-240A UV-vis spectrophotometers (resolution: 0.1 nm, spectral bandwidth: 0.25 nm, wavelength repeatability: ±0.1 nm, wavelength accuracy: ±0.3 nm). The Fourier-transform infrared (FTIR) spectrum of the PANI:PSS was recorded with a PerkinElmer FT-IR spectrometer (scan resolution=4 cm⁻¹). The sheet resistance of various films was measured using a 4-point probe method. SEM images of various films were obtained through a field emission scanning electron microscope (JSM 7610F from JEOL, Ltd.) (accelerating voltage: 0.1 to 30 kV, probe current: several pA to 200 nA, magnification: 25 to 1,000,000).

To observe the effect of mechanical stress on the electrical and optical properties of the IZTO film, which was treated unlike the pure IZTO film, the sheet resistance and transmittance spectrum of the film were recorded after different bending cycles (0-20,000 times). For the bending test, a bending tester with a bending radius of 3R and a bending frequency of 6 Hz was used. To obtain more reliable results, many samples were tested under the same conditions, multiple data sets were collected, and the data was analyzed through existing statistical procedures to determine the average value and standard deviation.

### Method of Confirming Whether PANI:PSS Interlayer is Formed

Before observing the properties, whether the PANI:PSS interlayer was sufficiently formed on the IZTO film was confirmed. To confirm the polymerization, the Fourier-transform infrared (FTIR) spectrum of the PANI:PSS film were observed. In the FRIR spectrum, two different peaks appear at 1560 cm⁻¹ and 1485 cm⁻¹. The two peaks correspond to the stretching of the quinoid and benzenoid rings, which indicates that PANI is present in the IZTO film.

In addition, distinct peaks appear at 677 cm⁻¹, 1010 cm⁻¹, 1035 cm⁻¹, 1128 cm⁻¹ and 1180 cm⁻¹ in the spectrum. Among them, the peak at 677 cm⁻¹ is related to the C—S bond stretching of the benzene ring, whereas the peak around 1010 cm⁻¹ is due to the in-plane bending vibration of the benzene ring. In addition, the peaks at 1035 cm⁻¹ and 1128 cm⁻¹ are caused by the in-plane skeletal vibration of the benzene ring and the symmetric stretching vibration of the sulfone group, respectively. Finally, the broad peak around 1180 cm⁻¹ corresponds to the asymmetric stretching vibration of the SO₃— group, which indicates that PSS is present in the IZTO film.

Through the observation of the FTIR spectrum described above, it can be confirmed that a PANI:PSS interlayer is formed on the IZTO film. Hereinafter, with reference to the drawings, the properties of the IZTO film on which the PANI:PSS interlayer is formed will be described.

### Optical Properties

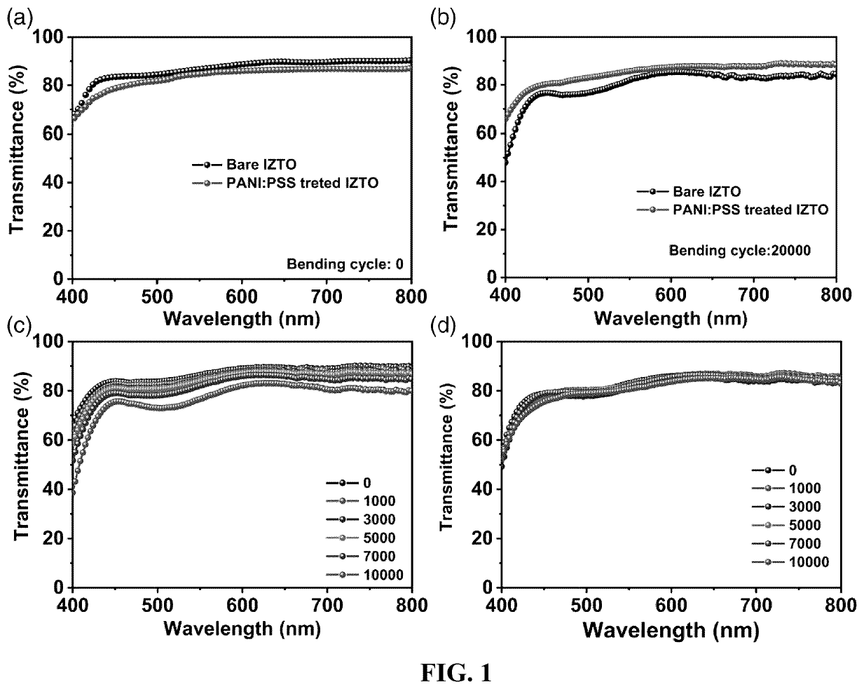

FIG. 1 is a set of graphs showing the transmittance spectra of an IZTO film with a PANI:PSS interlayer according to an embodiment of the present invention and a conventional IZTO film before and after bending cycles, respectively. FIG. 1A shows the transmittance of each film before bending, FIG. 1B shows the transmittance of each film after 20,000 bending cycles, and FIGS. 1C and 1D show the transmittance of a conventional IZTO film and an IZTO film with a PANI:PSS interlayer, respectively, after various numbers of bending cycles.

Referring to FIG. 1A, the two films show the same transmittance (including a slight drop) in the frequency range of 400-800 nm under the “0” bending cycle condition. Since the transmittance of the IZTO film with a PANI:PSS interlayer is lower than that of the conventional IZTO film, there is almost no decrease in transmittance.

Referring to FIG. 1B, it can be seen that the transmittance of the IZTO film with a PANI:PSS interlayer is greater than that of the conventional IZTO film after 20,000 bending cycles. In addition, referring to FIGS. 1C and 1D, the transmittance spectra of the conventional IZTO film and the IZTO film with a PANI:PSS interlayer recorded after various bending cycles show that the number of bending cycles significantly affects the transmittance of the IZTO film. Specifically, transmittance gradually decreases as the number of bending cycles increases, but in the case of the IZTO film with a PANI:PSS interlayer, the reduction rate of transmittance as the number of bending cycles increases is much lower than that of the conventional IZTO film.

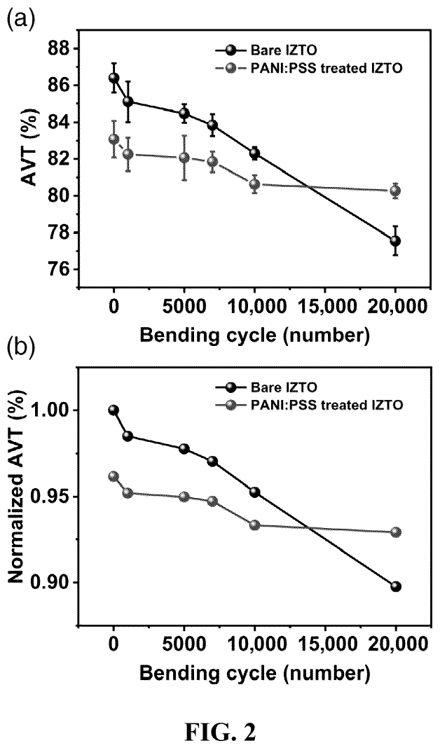

To more accurately quantify the effect of the PANI:PSS interlayer, the AVT values of each film were calculated after various bending cycles. FIG. 2 is a set of graphs showing AVT and normalized AVT values calculated at different numbers of bending cycles for the IZTO film with a PANI:PSS interlayer according to an embodiment of the present invention and the conventional IZTO film. Referring to FIG. 2B, it can be seen that the conventional IZTO film may have 89% of its initial AVT value after 20,000 bending cycles. On the other hand, it can be seen that the IZTO film with a PANI:PSS interlayer according to an embodiment of the present invention may have 95.00% of its initial AVT value even after the same number of bending cycles.

### Electrical Properties

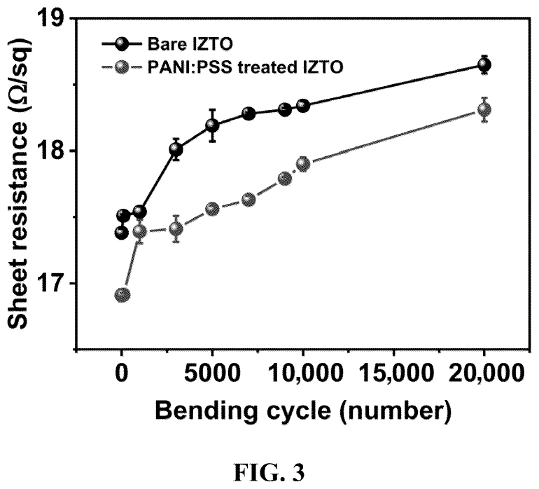

FIG. 3 is a graph showing the sheet resistance values of the conventional IZTO film and the IZTO film with a PANI:PSS interlayer according to an embodiment of the present invention.

In addition to transmittance, sheet resistance is significant for IZTO films. Therefore, the effect of bending treatment on the sheet resistance of each film was examined. FIG. 3 shows the sheet resistance values of each film (summarized in Table 1) measured at different bending cycles. It can be seen that at the initial stage (i.e., “0” bending cycles), the sheet resistance value of the conventional IZTO film is 17.38 Ω/sq, whereas the sheet resistance value of the IZTO film with a PANI:PSS interlayer is 16.91 Ω/sq, which has decreased due to the PANI:PSS interlayer. Since the conductivity of the PANI:PSS film is quite high, the sheet resistance value of the IZTO film with a PANI:PSS interlayer is slightly lower than that of the conventional IZTO film.

In addition, as the number of bending cycles increases, although the sheet resistance value of the conventional IZTO film increases to 18.65 Ω/sq, the sheet resistance value of the IZTO film with a PANI:PSS interlayer increases to 18.31 Ω/sq, which is lower than that of the conventional IZTO film. From these results, it is clear that when an IZTO film has PANI:PSS as an interlayer, the PANI:PSS interlayer has a positive effect and may improve the performance of the IZTO film as a flexible transparent electrode.

TABLE 1

| | Sheet resistance (Ω/sq) | | | | | |
|---|---|---|---|---|---|---|
| | Number of bending cycles | | | | | |
| Films | 0 | 3,000 | 5,000 | 7,000 | 10,000 | 20,000 |
| Bare IZTO | 17.38 | 18.01 | 18.19 | 18.28 | 18.34 | 18.65 |
| PANI:PSS | 16.91 | 17.39 | 17.56 | 17.63 | 17.90 | 18.31 |
| treated IZTO | | | | | | |

[Table 1] Summary of Sheet Resistance Values for Each Film after Different Bending Cycles

### Correlation Between Morphology and Optical and Electrical Properties

FIG. 4 is a set of SEM images of the conventional IZTO film and the IZTO film with a PANI:PSS interlayer according to an embodiment of the present invention immediately before and after bending cycles, and SEM images of each film were recorded immediately before and after 20,000 bending cycles to find out the exact reason for having the optical and electrical properties described above.

In FIG. 4A (conventional IZTO film) and FIG. 4D (IZTO film with PANI:PSS interlayer), the surface morphology of each film is identical, and various spots/protrusions are present on the surface of both films, which may indicate aggregated IZTO on the film surfaces. Referring to FIG. 4, it can be seen that after 20,000 bending cycles, the number of cracks occurring in the conventional IZTO film (FIGS. 4B and 4C) is greater than that of cracks occurring in the IZTO film with a PANI:PSS interlayer (FIGS. 4E and 4F).

Since a larger number of cracks occur on the surface of the conventional IZTO film compared to the IZTO film with a PANI:PSS interlayer, the possibility of light scattering is higher for the conventional IZTO film, and it can be understood that compared to the IZTO film with a PANI:PSS interlayer, the conventional IZTO film has a lower transmittance after 20,000 bending cycles due to light scattering caused by cracks.

As seen above, in the present invention, PANI:PSS was synthesized at a weight ratio PANI to PSS of 1:1 and then applied on a transparent IZTO film deposited on a flexible PI substrate.

Through experiments, it was confirmed that the mechanical stability of the IZTO film was significantly improved by forming the organic semiconductor PANI:PSS interlayer.

Specifically, when comparing the transmittance spectra and sheet resistance values recorded before and after 20,000 bending cycles of a conventional IZTO film and an IZTO film with a PANI:PSS interlayer, it was revealed that effect of mechanical stress (i.e. bending) on the optical properties (transmittance) and electrical properties (sheet resistance) was significantly reduced because the occurrence of cracks in the inorganic IZTO layer is prevented due to the formation of the PANI:PSS interlayer.

According to the present invention, it is possible to manufacture a transparent indium zinc tin oxide electrode with significantly improved retention rate of the initial average visible transmittance (AVT) even after bending cycles.

According to the present invention, it is possible to manufacture a transparent indium zinc tin oxide electrode with reduced sheet resistance.

According to the present invention, it is possible to manufacture a transparent indium zinc tin oxide electrode with improved mechanical stability by preventing fractures in the inorganic IZTO layer.

The preferred embodiments of the present invention described above are disclosed for illustrative purposes, and those skilled in the art will be able to make various modifications, changes and additions within the spirit and the scope of the present invention, which should be considered as falling within the scope of the patent claims. In addition, since those skilled in the art to which the present invention pertains can make various substitutions, modifications and changes without departing from the technical spirit of the present invention, the present invention is not limited to the above-described embodiments and attached drawings.

In the above-described exemplary system, the methods are described on the basis of a flowchart as a series of steps or blocks, but the present invention is not limited to the order of the steps, and some steps may occur in a different order or may occur simultaneously as described above. In addition, those skilled in the art will understand that the steps described in the flowchart are not exclusive and that other steps may be included or one or more steps in the flowchart may be deleted without affecting the scope of the present invention.

What is claimed is:

1. A transparent IZTO electrode comprising a PANI:PSS interlayer formed on an upper surface of an IZTO film.

2. The electrode of claim 1, wherein the weight ratio of PANI to PSS of the PANI:PSS is 1:1.

3. The electrode of claim 1, wherein the interlayer is formed by spin coating the PANI:PSS on the upper surface of the IZTO film at 3,000 rpm for 60 seconds.
